(19) United States
(12) Patent Application Publication
(10) Pub. No.: US 2009/0273021 A1
(43) Pub. Date: Nov. 5, 2009

(54) SEMICONDUCTOR DEVICE AND METHOD FOR MANUFACTURING THE SAME

(76) Inventors: Katsuyuki SEKINE, Yokohama-shi (JP); Daisuke Nishida, Yokkaichi-shi (JP); Ryota Fujitsuka, Yokohama-shi (JP); Yoshio Ozawa, Yokohama-shi (JP); Katsuaki Natori, Yokohama-shi (JP); Takashi Nakao, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/432,453

(22) Filed: Apr. 29, 2009

(30) Foreign Application Priority Data
Apr. 30, 2008 (JP) 2008-119296

(51) Int. Cl. H01L 29/792; H01L 21/28

(52) U.S. Cl. 257/326; 438/591; 257/E29.309; 257/E21.21

(57) ABSTRACT

A semiconductor device includes a semiconductor substrate, a tunnel insulating film on the semiconductor substrate, a charge storage layer on the tunnel insulating film, a block insulating film on the charge storage layer, and a control gate electrode on the block insulating film, the charge storage layer including a plurality of layers including first and second charge storage layers, the second charge storage layer being provided on a nearest side of the block insulating film, the first charge storage layer being provided between the tunnel insulating film and the second charge storage layer, the second charge storage layer having a higher trap density than the first charge storage layer, the second charge storage layer having a smaller band gap than the first charge storage layer, and the second charge storage layer having a higher permittivity than the first charge storage layer and a silicon nitride film.

### CROSS-REFERENCE TO RELATED APPLICATIONS

This application is based upon and claims the benefit of priority from prior Japanese Patent Application No. 2008-119296, filed Apr. 30, 2008, the entire contents of which are incorporated herein by reference.

### BACKGROUND OF THE INVENTION

1. Field of the Invention

The present invention relates to a semiconductor device including an electrically rewritable nonvolatile semiconductor memory, and a method for manufacturing the same.

2. Description of the Related Art

A SONOS memory has been known as one of electrically rewritable nonvolatile semiconductor memories. The SONOS memory is obtained by replacing material of a gate electrode of a metal-oxide-nitride-oxide-semiconductor (MONOS) memory with semiconductor.

As an example of conventional SONOS memory, it is know that includes a tunnel insulating film (SiO₂)/charge storage layer (SiN_{X})/block insulating film (SiO₂ or Al₂O₃). Jpn. Pat. Appln. KOKAI Publication 2006-229233 proposes a method that makes the memory window compatible with the charge retention characteristic by introducing a double-layered structure into the charge storage layer. However, even if the method is employed, it is difficult to make the memory window compatible with the charge retention characteristic good enough to realize multi-value cell.

### BRIEF SUMMARY OF THE INVENTION

According to an aspect of the present invention, there is provided a semiconductor device comprising: a semiconductor substrate; a tunnel insulating film provided on the semiconductor substrate; a charge storage layer provided on the tunnel insulating film; a block insulating film provided on the charge storage layer; and a control gate electrode provided on the block insulating film, the charge storage layer comprising a plurality of layers including first and second charge storage layers, the second charge storage layer being provided on a nearest side of the block insulating film, the first charge storage layer being provided between the tunnel insulating film and the second charge storage layer, the second charge storage layer having a higher trap density than the first charge storage layer, the second charge storage layer having a smaller band gap than the first charge storage layer, and the second charge storage layer having a higher permittivity than the first charge storage layer and a silicon nitride film.

According to an aspect of the present invention, there is provided a method for manufacturing a semiconductor device comprising: forming a tunnel insulating film on a semiconductor substrate; forming a charge storage layer on the tunnel insulating film, the charge storage layer comprising a plurality of layers including first and second charge storage layers; performing heat treatment to the charge storage layer in an atmosphere including chlorine; forming a block insulating film on the charge storage layer, and forming a control gate electrode on the block insulating film, wherein the second charge storage layer being provided on a nearest side of the block insulating film, the first charge storage layer being provided between the tunnel insulating film and the second charge storage layer, the second charge storage layer having a higher trap density than the first charge storage layer, the second charge storage layer having a smaller band gap and the second charge storage layer having a higher permittivity than the first charge storage layer and a silicon nitride film.

According to another aspect of the present invention, there is provided a method for manufacturing a semiconductor device comprising: forming a tunnel insulating film on a semiconductor substrate; forming a charge storage layer on the tunnel insulating film the charge storage layer comprising a plurality of layers including first and second charge storage layers; forming a block insulating film on the charge storage layer in an atmosphere including chlorine; and forming a control gate electrode on the block insulating film, wherein the second charge storage layer being provided on a nearest side of the block insulating film, the first charge storage layer being provided between the tunnel insulating film and the second charge storage layer, the second charge storage layer having a higher trap density than the first charge storage layer, the second charge storage layer having a smaller band gap than the first charge storage layer, and the second charge storage layer having a higher permittivity than the first charge storage layer and a silicon nitride film.

### BRIEF DESCRIPTION OF THE SEVERAL VIEWS OF THE DRAWING

FIG. 1 is a cross-sectional view showing a semiconductor device according to a first embodiment;

FIG. 2 is a cross-sectional view showing a semiconductor device according to a second embodiment;

FIG. 3 is a view to explain a modification example of the semiconductor device according to the second embodiment;

FIG. 4 is a cross-sectional view showing a semiconductor device according to a third embodiment;

FIG. 5 is a cross-sectional view showing a semiconductor device according to a fourth embodiment;

FIG. 6 is a view to explain a modification example of the semiconductor device according to the fourth embodiment;

FIG. 7 is a cross-sectional view showing a semiconductor device according to a fifth embodiment;

FIG. 8 is a cross-sectional view to explain the process of manufacturing a semiconductor device according to a fifth embodiment following FIG. 7;

FIG. 9 is a cross-sectional view to explain the process of manufacturing a semiconductor device according to a fifth embodiment following FIG. 8;

FIG. 10 is a cross-sectional view to explain the process of manufacturing a semiconductor device according to a fifth embodiment following FIG. 9;

FIG. 11 is a cross-sectional view to explain the process of manufacturing a semiconductor device according to a fifth embodiment following FIG. 10;

FIG. 12 is a cross-sectional view to explain the process of manufacturing a semiconductor device according to a fifth embodiment following FIG. 11;

FIG. 13 is a cross-sectional view to explain the process of manufacturing a semiconductor device according to a fifth embodiment following FIG. 12;

FIG. 14 is a cross-sectional view to explain the process of manufacturing a semiconductor device according to a fifth embodiment following FIG. 13;

FIG. 15 is a cross-sectional view to explain the process of manufacturing a semiconductor device according to a fifth embodiment following FIG. 14; and

FIG. 16 is a graph to explain the effect of the method for manufacturing a semiconductor device according to a fifth embodiment.

### DETAILED DESCRIPTION OF THE INVENTION

Various embodiments of the present invention will be hereinafter described with reference to the accompanying drawings.

### First Embodiment

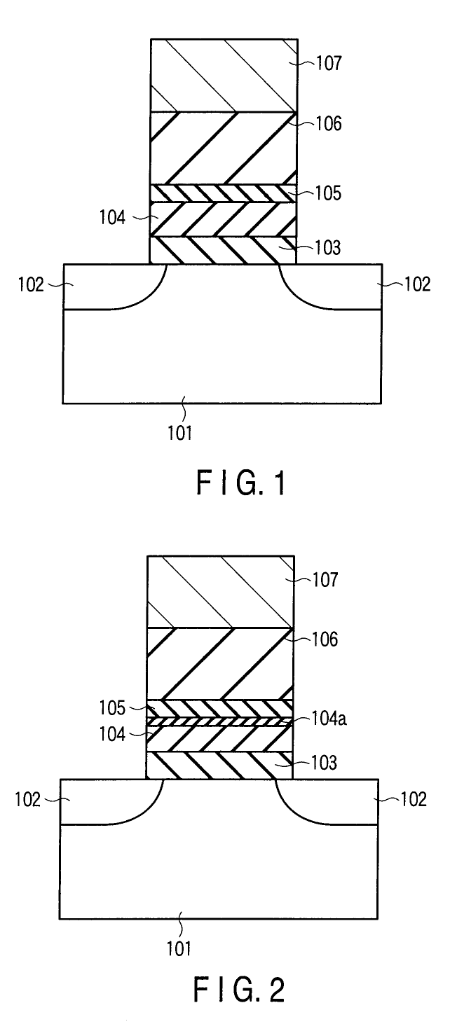

FIG. 1 is a cross-sectional view showing a semiconductor device according to a first embodiment. In FIG. 1, 101 denotes a semiconductor substrate, and a pair of source/drain regions 102 is provided on a surface of the semiconductor substrate 101. Here, the semiconductor substrate 101 is a silicon substrate, however, an SOI substrate, or a semiconductor substrate formed of a semiconductor except silicon such as SiGe may be used. The surface of the semiconductor substrate 101 is not provided with the source/drain regions 102, instead, the surface of the semiconductor substrate 101 may be provided with a uniform diffusion region to provide a cell transistor which operates in depletion mode.

A tunnel insulating film 103 is provided on the surface (channel region) of the semiconductor substrate 101 between source/drain regions 102. A silicon nitride film (first charge storage layer) 104 constituting a part of a charge storage layer is provided on the tunnel insulating film 103.

An insulating film (second charge storage layer) 105 containing Hf or Zr constituting a part of the charge storage layer is provided on the silicon nitride film 104. This insulating film (hereinafter, referred to as Hf/Zr insulating film) 105 containing Hf or Zr is, for example, a HfSiON film, a HfAlO film, a HfAlON film, a HfO₂ film (Hafnium oxide), HfON film, a ZrSiON film, a ZrAlO film, a ZrO₂ film and a ZrON film.

A high-k insulating film 106 as a block insulating film is provided on the Hf/Zr insulating film 105. A control gate electrode 107 is provided on the high-k insulating film 106. The control gate electrode 107 comprises, for example, polycrystalline silicon or metal. In a case where the control gate electrode 107 comprises polycrystalline silicon, a SONOS memory is provided, in a case where the control gate electrode 107 comprises metal, a MONOS memory is provided. In the following description, the term “SONOS” is used for both cases of SONOS and MONOS for simplicity.

The silicon nitride film 104 constituting a part of the charge storage layer may have N/Si composition ration which is higher stoichiometric ration (4/3) of a silicon nitride film (SiₓN_{y}, y/x=4/3). When the silicon nitride film 104 is set such a nitrogen rich, the charge trap density is reduced, and the trap level is deepened. This has a beneficial effect on deterioration of the charge retention characteristic resulting from electron leakage from the silicon nitride film 104 to the semiconductor substrate 101 via the tunnel insulating film 103.

However, if the charge trap density of the silicon nitride film 104 is simply reduced, sufficient write window characteristic is not obtained. In particular, if the charge storage layer having the stacked structure of silicon nitride films having different composition shown in the Jpn. Pat. Appln. KOKAI Publication 2006-229233 is used, the sufficient write window characteristic is not obtained.

On the contrary, if the charge storage layer of the present embodiment is used, as the Hf/Zr insulating film 105 has a charge trap ability of ten times to 100 times as much as the silicon nitride film, the charge trap density rather increases on the whole of SONOS structure. Therefore, according to the present embodiment, it is possible to realize both of the memory window wide enough to realize multi-value cell and the charge retention characteristic.

If the impurity such as nitrogen or carbon contained in the Hf/Zr insulating film 105 constituting a part of the charge storage layer diffuses to the surface of the semiconductor substrate 101 on which a channel is to be generated, the impurity turns out to be fixed charge in the semiconductor substrate 101. As a result, the threshold voltage (Vth) of SONOS transistor varies, and the variation of threshold voltage between cells increases, thereby the cell suffers difficulty in designing.

But, in a case of the structure of charge storage layer of the present embodiment, the silicon nitride film 104 gives a beneficial effect that the impurity such as nitrogen or carbon contained in the Hf/Zr insulating film 105 is prevented from diffusing into the semiconductor substrate 101 by heat process for forming the SONOS structure. This effect of the diffusion prevention increases as the nitrogen concentration is higher. Therefore, it is preferable to set the silicon nitride film 104 constituting a part of the charge storage layer in nitrogen rich from a point of view for preventing the impurity diffusion view, too.

The silicon nitride film 104 may contain oxygen much so long as it does not lose an anti-diffusion ability against carbon or nitrogen. The silicon nitride film 104 containing a proper amount of oxygen realizes a reduction of charge trap density. Therefore, this is effective to preventing deterioration of charge retention characteristic resulting from electron leakage from the silicon nitride film 104 into the semiconductor substrate 101 via the tunnel insulating film 103.

In addition, according to the research by the inventors of the present application, it is found out that when the Hf/Zr insulating film 105 is formed directly on the tunnel insulating film 103, the writing speed is lowered. The reason is thought as follows. That is, since the Hf/Zr insulating film 105 has very high charge trap ability, when the Hf/Zr insulating film 105 is formed directly on the tunnel insulating film 103, an interface between the tunnel insulating film 103 and the Hf/Zr insulating film 105 shows a raising of potential that is reduced by charge trap, and the tunnel insulating film 103 is not applied with electric field.

However, according to the structure of the present embodiment, as the Hf/Zr insulating film 105 having very high charge trap ability and the tunnel insulating film 103 are separated by the silicon nitride film 104, the reduction of writing speed is sufficiently suppressed even if the Hf/Zr insulating film 105 having very high charge trap ability is used as a part of the charge storage layer.

In addition, when the charge storage layer having the stacked structure of the silicon nitride films having different composition rations as shown in Jpn. Pat. Appln. KOKAI Publication 2006-229233, the silicon-rich silicon nitride film exists in the interface with the block insulating film. The trap level density increases by the silicon-rich silicon nitride film, but the trap level decreases. Therefore, the charge retention characteristic is not obtained sufficiently.

On the contrary, when the nitrogen-rich silicon nitride film is used as the silicon nitride film 104 in the SONOS structure of the present embodiment, the nitrogen-rich silicon nitride film has deep electron trap level, therefore, even though the trap level density increases, the detrapping is hard to occur, and charge retention characteristic is greatly improved compared with the case of using the silicon-rich silicon nitride film.

As the structure of charge storage layer of the present embodiment, when the permittivity of material of the second charge storage layer (Hf/Zr insulating film 105) is higher than that of the first charge storage layer (silicon nitride film 104), the writing characteristic or the charge retention characteristic is improved since the electric field in the vicinity of the block insulating filed is relaxed at the time of writing or charge retaining.

That is, when the first and second charge storage layers satisfy D1<D2, Ψ1>Ψ2, ε1<ε2 as the present embodiment, it is possible to make the writing characteristic compatible with the charge retention characteristic sufficiently.

Here, D1 is trap density of the first charge storage layer to be formed on the tunnel insulating film, Ψ1 is band gap of the first charge storage layer, ε1 is permittivity of first charge storage layer, D2 is trap density of the second charge storage layer to be formed on the first charge storage layer, Ψ2 is band gap of the second charge storage layer, and ε2 is permittivity of second charge storage layer.

In most of cases, the higher the permittivity of material, the lower the band gap of the material, and the deeper the trap depth from the conduction band becomes. That is, as in the case of the present embodiment, when the relationship of ε1<ε2 is satisfied, the relationship φ1 (trap depth of first charge storage layer)<φ2 (trap depth of second charge storage layer) is obtained. Moreover, when the materials having different band gaps are stacked, the level depth to be a pass of trap assist tunnel current differs for each of the materials, and leakage of the retained charge due to the trap assist tunnel current is suppressed. Thereby, the charge retention characteristic is improved.

The film thickness of the tunnel insulating film 103 is typically about 2 to 8 nm.

The film thickness of the silicon nitride film 104 is typically about 2 to 8 nm.

The film thickness of the Hf/Zr insulating film 105 is typically about 0.5 to 5 nm. Since the Hf/Zr insulating film 105 has sufficient charge trap ability, sufficient write characteristic is obtained even though the film thickness is about 0.5 to 3 nm.

Therefore, when the films 104 and 105 are designed to satisfy d1>d2, where d1 is the film thickness of the silicon nitride film 104, d2 is the film thickness of the Hf/Zr insulating film 105, suppression of the diffusion of impurity into the semiconductor substrate 101, suppression of the deterioration of the charge retention characteristic caused by the charge leakage to the tunnel insulating film 103 side, and sufficient writing characteristic is achieved, thereby the effect of the present embodiment (the compatibility between the memory window wide enough to realize multi-value and the charge retention characteristic) is easily obtained.

Relating to the Hf/Zr insulating film 105, when the above mentioned HfSiON film, HfAlO film, HfAlON film, HfO₂ film, HfON film, ZrSiON film, ZrAlO film, ZrO₂ film or ZrON film is used, the compatibility between the wide memory window enough to realize multi-value and the charge retention characteristic is achieved. In addition, the insulating film 105 containing Hf or Zr is not limited to the monolayer, and the insulating film 105 may be a laminated layer.

Even if a silicon oxide film is used as the block insulating film, the effect is obtained, however it is advantageous to use the high-k insulating film 106 as the present embodiment in respect to thinning the electrical film thickness as the SONOS. The high-k insulating film for the candidate of the block insulating film, an A1₂O₃ film is suitable in light of band alignment, but a HfAlO film, a HfSiO film, or a Ta₂O₅ film may be used.

The following insulating films can be used as the tunnel insulating film 103 for instance. One example is, a silicon oxide film formed in oxidization atmosphere at 800 to 1000° C. Another example is, a silicon oxynitride film obtained by nitrifying the silicon oxide film formed as above in NO gas atmosphere, NH₃ atmosphere or N radical atmosphere. When the silicon oxynitride film is used as the tunnel insulating film 103, as the electrical potential barrier to holes is reduced, and erasing speed is fastened.

The silicon nitride film 104 constituting a part of the charge storage layer may be formed in the following manner. For example, the film 104 is formed by LPCVD process using DCS (SiH₂Cl₂) and NH₃ as source gases at the temperature range (deposition temperature) from 600 to 800° C. Alternatively, the film 104 is formed by ALD process using DCS and NH₃ as source gases at the temperature range from 400 to 600° C.

When the silicon nitride film 104 is formed using LPCVD process, the density is high directly after the deposition (As Depo), and this makes it possible to form the silicon nitride film 104 having high anti-diffusion ability against carbon and nitrogen.

On the other hand, when the silicon nitride film 104 is formed using the ALD process, thickness controllability in a thin film thickness area is improved, and this makes it possible to form the silicon nitride film 104 having good morphology on the tunnel insulating film 103. When the film 104 is formed by ALD process, it requires additional heat treatment to make SiN densified in some cases.

Even if either of LPCVD and ALD processes is used, it is possible to form both of a normal silicon nitride film and a nitrogen-rich silicon nitride film by changing the gas supply ratio of DCS and NH₃.

In addition, when the silicon nitride film 104 is formed by ALD process, amino silane such as BTBAS and NH₃ may be used as source gases. On the other hand, when the silicon nitride film 104 is formed by LPCVD process, HCD (Si₂Cl₆) or TCS (SiHCl₃) may be used as the source gas.

The Hf/Zr insulating film 105 may be formed by using ALD process at the deposition temperature of 200-400° C., or may be formed using by MOCVD process at the deposition temperature of 500-800° C.

The above mentioned effect is obtained regardless of procures to form the silicon nitride film 104 and the Hf/Zr insulating film 105.

The Al₂O₃ film as the block insulating film 106 may be formed by using MOCVD process at the deposition temperature of 500-800° C., or may be formed by using ALD process at the deposition temperature of 200-400° C. The silicon oxide film as the block insulating film 106 is formed by using LPCVD process at the deposition temperature of 600-800° C.

### Second Embodiment

FIG. 2 is a cross-sectional view showing a semiconductor device according to a second embodiment. In the following figures, the portions corresponding to the portions shown in the previously mentioned drawings are denoted by the same reference numerals and omitted its detail explanation.

The present embodiment differs from the first embodiment in that a silicon oxynitride film 104a (third charge storage layer) is provided between the silicon nitride film 104 and the Hf/Zr insulating film 105.

As the silicon oxynitride film 104a has small amount of charge trap level, and moving of electrons between the silicon nitride film 104 and the Hf/Zr insulating film 105 is considerably suppressed even if the nitrogen-rich silicon nitride film is used as the silicon nitride film 104. Therefore, threshold voltage shift due to the variation of center of charge is suppressed, and the charge retention characteristic is greatly improved.

As a method for forming the silicon oxynitride film 104a, there is provided a method which includes exposing the surface of silicon oxynitride film 104a in an oxidizing agent, and there is provided a method which includes forming a silicon oxynitride film by using ALD process. As the former method, there is a method of forming the silicon oxynitride film 104a by thermal oxidization process, and in this case, for example, the oxidization in an oxidizing atmosphere of 600-1000° C. is performed to form the silicon oxynitride film 104a. In a case of latter method (ALD process), the film 104a is, for example, formed by using 3DMAS, BTBAS and O₃ as the source gases.

The method for forming the silicon oxynitride film by oxidizing the surface of silicon nitride film 104 provides better characteristic. Such the silicon oxynitride film can be formed without intentionally carrying out the process of oxidizing the silicon oxide film. Because, the silicon oxynitride film 104a can be formed between the silicon nitride film 104 and the Hf/Zr insulating film 105 during the step of annealing the Hf/Zr insulating film 105 which is performed after the step of forming the Hf/Zr insulating film 105 on the silicon nitride film 104. The film thickness of the silicon oxynitride film 104a is preferably 1 to 3 nm.

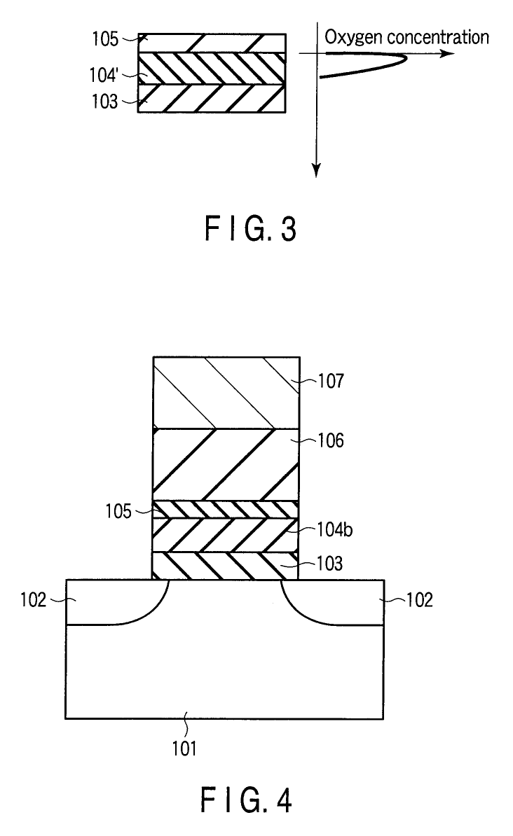

In the present embodiment, the example of forming the silicon oxynitride film 104a on the silicon nitride film 104 is explained, however as shown in FIG. 3, a silicon oxynitride film 104a′ may be used as the first charge storage layer whose oxygen concentration is high on the side of Hf/Zr insulating film 105 and low on the side of tunnel insulating film 103.

### Third Embodiment

FIG. 4 is a cross-sectional view showing a semiconductor device according to a third embodiment.

The third embodiment differs from the first embodiment in that an alumina film 104b is used as the first charge storage layer instead of the silicon nitride film 104.

The alumina film 104b has smaller amount of charge trap density than the silicon nitride film 104. Therefore, compared with the case of using the silicon nitride film 104, the shift of threshold voltage due to the charge leakage via the tunnel insulating film 103 is further suppressed. Thereby, the charge retention characteristic is further improved.

In addition, by replacing the silicon nitride film 104 with the alumina film 104b, the tunnel insulating film 103 is made thinner while the charge retention characteristic is maintained, and this makes it possible to improve the writing speed.

Furthermore, as the alumina film 104b has higher permittivity than the silicon nitride film 104, the alumina film 104b is advantageous for thinning the electrical film thickness as the whole of the SONOS.

The tunnel insulating film is preferably a silicon oxide film. Because, the diffusion of carbon, nitrogen and aluminum in the alumina film 104b into the semiconductor substrate 101 can be prevented.

As a method for forming the silicon oxynitride film, there is provided a method which includes forming a silicon oxide film in an oxidizing atmosphere of 800-1000° C., and thereafter introducing nitrogen in a surface of the silicon oxide film by using radical nitriding. The nitridation of the silicon oxide film is not limited to radical nitriding, but thermal nitridation may be used. As an example of the nitridation, there is provided a heat treatment which is performed in an ammonium atmosphere of 700-1000° C.

In a case where that the alumina film is formed as the first charge storage layer and the HfO₂ or HfAlO film is formed as the second charge storage layer, the number of steps is reduced since the a series of steps from the step of forming the first charge storage layer to the step of block insulating film is performed in the same apparatus. Further, since the interface level generated for each of interface between two stacked layers is reduced, the charge retention characteristic is improved, or the degradation of cell characteristic after receiving the write/erase stress is prevented.

### Fourth Embodiment

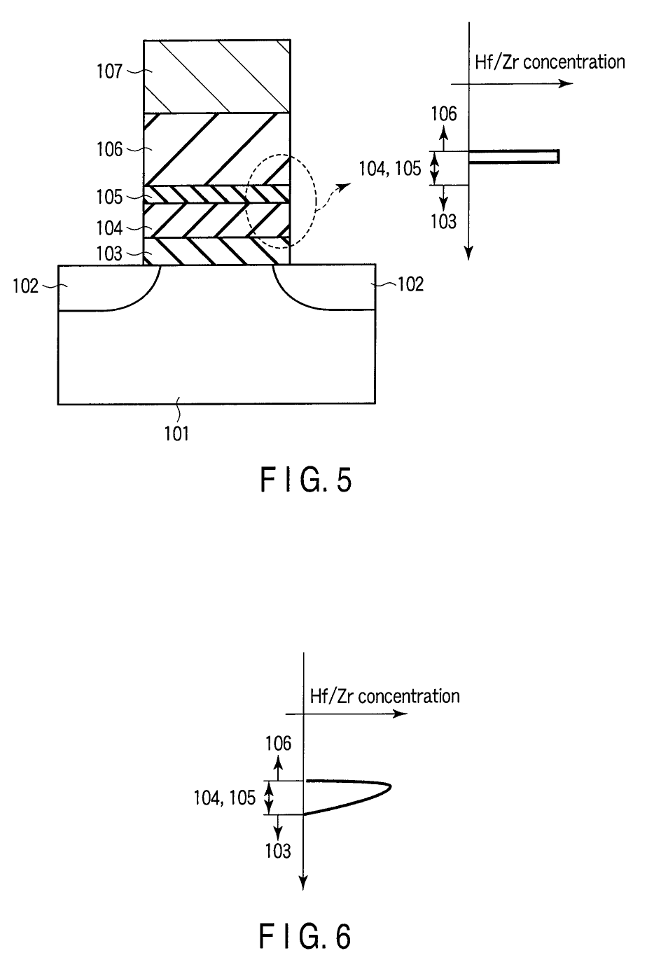

FIG. 5 is a cross-sectional view showing a semiconductor device according to a fourth embodiment.

A charge storage layer having a stacked structure of the silicon nitride film 104 and the Hf/Zr insulating film 105 has a concentration distribution of Hf or Zr (element profile). In the concentration distribution, the concentration of Hf or Zr is high on a side of the block insulating film 106, the concentration of Hf or Zr has a peak on the side of the block insulating film 106, and the concentration of Hf or Zr is low on a side of the tunnel insulating film 103. FIG. 5 shows the concentration distribution in which Hf or Zr concentration of the silicon nitride film 104 is zero, or the silicon nitride film 104 contains Hf or Zr, but the concentration of Hf or Zr is zero on the side of the interface with the tunnel insulating film 103. Thereby, the charge trap density of the block insulating film 106 is rendered to be small, further, as trap assist tunnel current in the block insulating film 106 is suppressed, the charge retention characteristic is improved.

In addition, as shown in FIG. 6, when the change of concentration of Hf or Zr on the side of block insulating film 106 is set more steeply than the change of concentration of Hf or Zr on the side of tunnel insulating film 10, the interface between the silicon nitride film 104 and the Hf/Zr insulating film 105 is blurred, and the generation of the level at the interface between the silicon nitride film 104 and the Hf/Zr insulating film 105 is suppressed. Therefore, the charge retention characteristic is further improved. In addition, even if the alumina film 104b is used as the first charge storage layer instead of the silicon nitride film 104, the same effect is obtained.

It is preferable to use ALD process for forming the above mentioned concentration distribution. For example, in a case where the first charge storage layer is an alumina film, the second charge storage layer is a HfALO film, and the block insulating film is an alumina film, Hf concentration of the film is accurately controlled by cycle ratio of alumina and hafnium if ALD process is used.

As the another method of forming the concentration distribution, there is provided a method which includes forming a first charge storage layer of silicon nitride or alumina and a second charge storage layer containing Hf or Zr, thereafter, performing a high temperature heat treatment. At the time of the high temperature heat treatment, Hf or Zr diffuses from the second charge storage layer into the first charge storage layer. Therefore, by controlling the high temperature heat treatment, the desired concentration distribution of Hf or Zr is realized.

### Fifth Embodiment

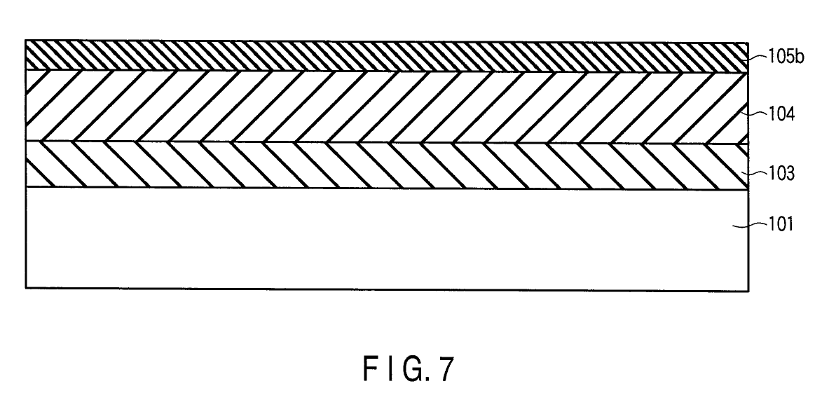

FIGS. 7 to 15 are cross-sectional views showing the method of manufacturing a semiconductor device according to a fifth embodiment.

[FIG. 7]

A tunnel insulating film 103 of a silicon oxynitride is formed on a semiconductor substrate 101 by using a method of combining silicon thermal oxidization and thermal nitridation. Here, the semiconductor substrate 101 is a silicon substrate.

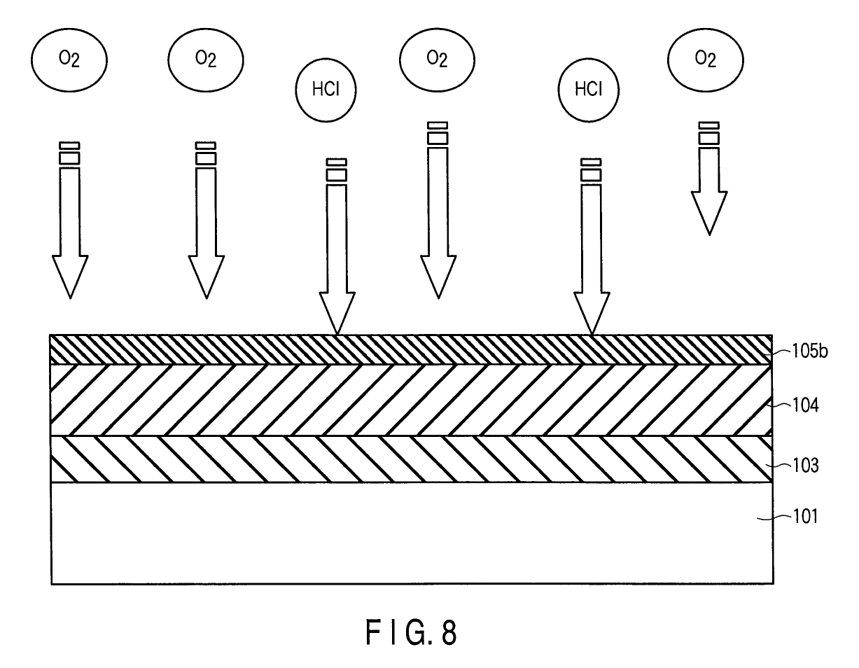

A silicon nitride film 104 as the first charge storage layer is formed on the tunnel insulating film 103 by LPCVD process. Thereafter, an alumina film (HfAlO film) 105b containing Hf as the second charge storage layer is formed on the silicon nitride film 104 by ALD process.

[FIG. 8]

Heat treatment in an oxidizing atmosphere containing chlorine as PDA (post deposition anneal) is performed to the HfAlO film 105. As the atmosphere containing chlorine, for example, an oxidizing atmosphere containing chlorine may be provided. The oxidizing atmosphere containing HCl is generated in the following manner for instance. That is, the oxidizing atmosphere containing chlorine is formed by mixing gas or spray containing HCl such as HCl, CH₃Cl, C₂H₄Cl₂ into oxidizing atmosphere comprising oxygen or vapor containing oxygen.

The following effect is obtained by performing the heat treatment (PDA process) in the oxidizing atmosphere to the HfAlO film 105b. The Organic material introduced from the ALD source at the time of forming the HfAlO film 105b is oxidized, thereby the material in the HfAlO film 105b is removed, and the structure of the HfAlO film 105b is densified.

In addition, in the present embodiment, as the oxidizing atmosphere containing HCl is used, and the charge trap density of the HfAlO film 105b is made higher, thereby the effect of improvement of the writing characteristic is also obtained.

Here, since the upper side surface of the HfAlO film 105b is particularly exposed in the oxidizing atmosphere containing HCl, the charge trap density of the HfAlO film 105b is made higher particularly in a vicinity of the surface of the HfAlO film 105b. That is, the position having high charge trap density is set away from the tunnel insulating film 103.

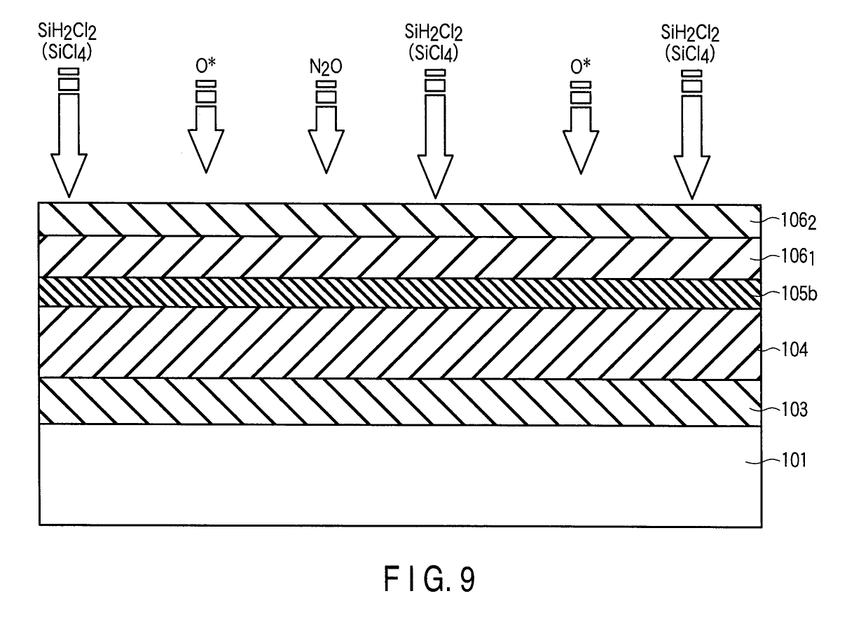

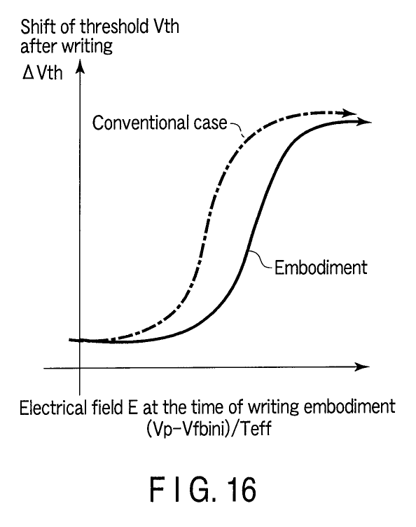

FIG. 16 shows retention characteristic when the HfAlO film 105b is exposed in the oxidizing atmosphere containing HCl and retention characteristic when the HfAlO film 105b is not exposed in the oxidizing atmosphere containing HCl (conventional case). As seen from FIG. 16, the present embodiment has better retention characteristic than the conventional case. The reason for this is as follows. That is, the charge trap density having advantageous distribution for improving the retention characteristic is formed in the HfAlO film 105b.

[FIG. 9]

An alumina film 106₁ and a silicon oxide film 106₂ are formed as a block insulating film on the HfAlO film 105b. The alumina film 106₁ is formed by ALD process, the silicon oxide film 106₂ is formed by LPCVD process.

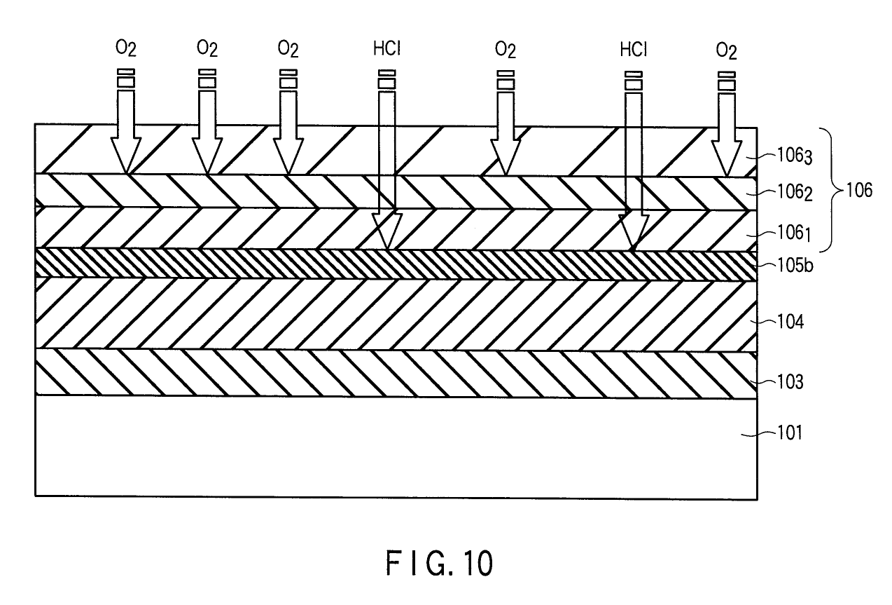

As source gases of the silicon oxide film 106₂, for example, SiH₂Cl₂ (dichloro-silane) gas and N₂O gas are used. When the SiH₂Cl₂ gas is used, the gas including Cl such as HCl which is decomposed matter of the SiH₂Cl₂ gas is generated in the atmosphere for forming the silicon oxide film 106₂. The Cl increases the charge trap density of the HfAlO film 105b. This effect is further enhanced by using a source gas containing more Cl than SiH₂Cl₂ gas such as SiHCl₃ or SiCl₄ (silicon tetra chloride). In FIG. 9, O* denotes oxygen radical.

[FIG. 10]

An alumina film 106₃ is formed on the silicon oxide film 106₂ by ALD process. In this manner, the block insulating film 106 (106₁ to 106₃) having the stacked structure of three layers is formed on the HfAlO film 105b.

Thereafter, a heat treatment in an oxidizing atmosphere containing HCl as the PDA process is performed to the alumina films 106₁ and 106₃. Such the PDA process using the atmosphere containing Cl also increases the charge trap density of the alumina film 106₃ is increased.

There is no need to carry out all of the foregoing PDA process using the atmosphere containing Cl and CVD process using a source gas containing Cl, the foregoing process may be properly omitted so long as the charge trap density of the HfAlO film 105b is sufficiently increased.

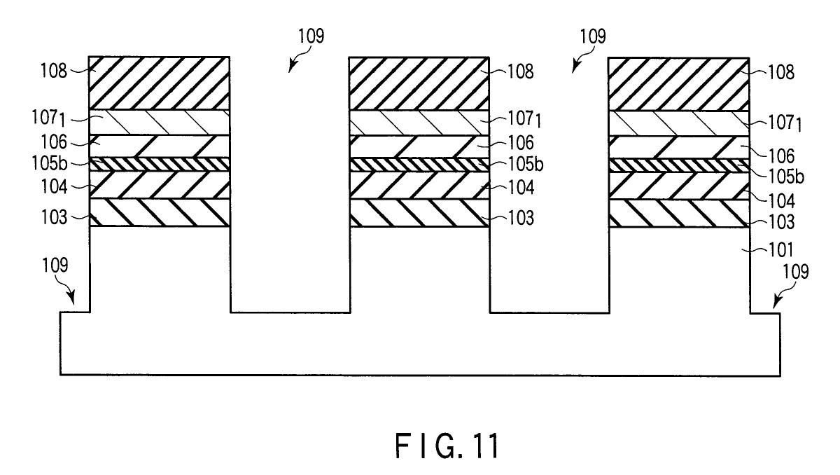

However, the atmosphere at the time of forming the alumina film 106₁ and 106₃ by ALD process or the atmosphere at the time of forming the silicon oxide film 106₂ by LPCVD process may be exposed to strong oxidizing atmosphere such as ozone as a consequence, in this case, the increased charge trap density of the HfAlO film 105b is reduced by oxidization in the strong oxidizing atmosphere. Such the reduction of the charge trap density is also occurred by the oxidizing atmosphere in the PDA process in a similar way. Therefore, only the once of exposure to the atmosphere including Cl is not good enough, so it is effective for increasing the charge trap density to repeat the exposure to the atmosphere including Cl as needed.

[FIG. 11]

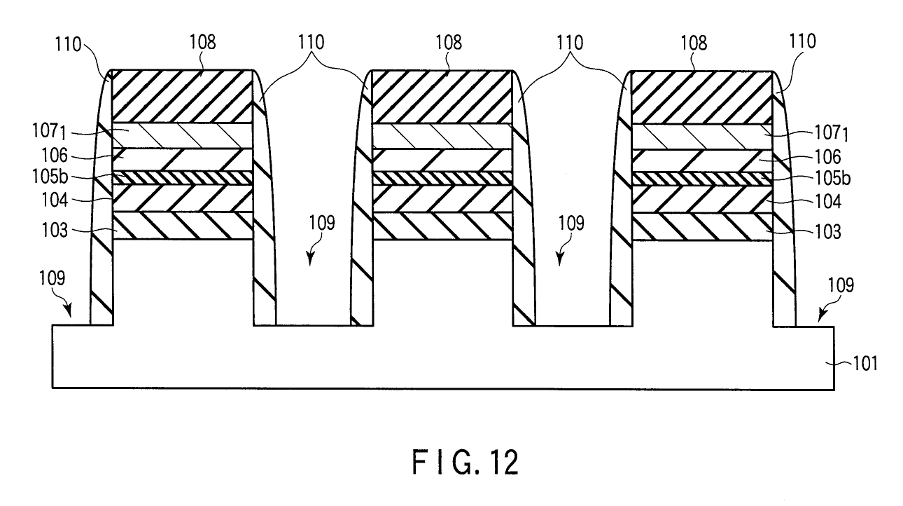

A conductive film (e.g., polycrystalline silicon film, metal film or metal nitride film which is conductor) to be a control gate electrode 107₁ is formed on the block insulating film. A mask (hard mask) 108 including a silicon nitride film and a silicon oxide film is formed on the conductive film, thereafter, the conductive film, block insulating film 106, HfAlO film 105, silicon nitride film 104, tunnel insulating film 103 and semiconductor substrate 101 are etched by RIE (reactive ion etching) process to form the control gate electrode 107₁ and a trench 109 for shallow trench isolation (STI).

[FIG. 12]

In general, after the forming of trench 109, a step of filling the trench 109 with an oxide film having high filling property (isolation insulating film) by CVD process using TEOS and ozone as source gases around a normal pressure is followed. In this step, the HfAlO film 105b (second charge storage layer) is exposed in ozone having relatively high partial pressure ozone, and further exposed in oxygen radical generated from the ozone. As a result, the silicon nitride film 104 (first charge storage layer) under the HfAlO film 105b is oxidized by catalytic action of metal such as Hf in the HfAlO film 105b. This oxidization reduces the amount of charge traps in the silicon nitride film 104, and thus, the charge trap density of the silicon nitride film 104 is reduced.

In addition, the charge trap density of the HfAlO film 105b is reduced since the amount of charge traps in the HfAlO film 105b in which the amount of charge traps is increased by the step of FIG. 9 is also reduced.

In order to prevent such the reduction of the charge trap density, the present embodiment carries out the following step. That is, an insulating film (spacer film) 110 is formed on a cell sidewall to protect the charge storage layer 104, 105b and the control gate electrode 1071 from the ozone atmosphere at the time of filling the trench 109.

Concretely, the insulating film (spacer film) 110 is formed on the cell sidewall by CVD process and RIE process (anisotropic etching). More concretely, the CVD process is performed in an atmosphere containing chlorine, further SiH₂Cl₂ and N₂O, or SiCl₄ and N₂O are used as source gases, which are carbon free.

In addition, the width of spacer film 110 is set such that oxygen radical generated from ozone is deactivated during the oxygen radical diffuses in the spacer film 110. For example, the width is 3 nm or more.

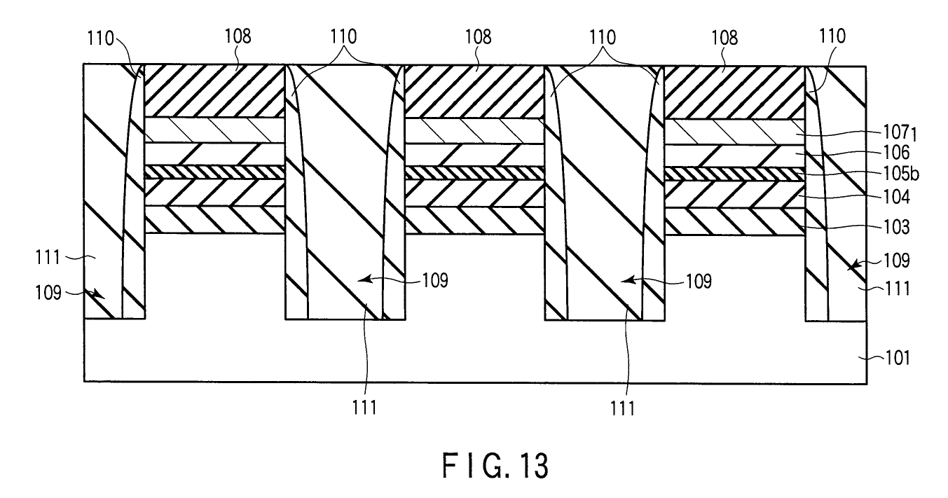

When the spacer film 110 is formed, the HfAlO film 105b is exposed to chlorine. Therefore, the damage of the HfAlO film 105b is repaired in which the damage is caused by the strong oxidizing agent such as ozone generated at the time of forming the spacer film 110. Further, the reduction of the charge trap density of the HfAlO film 105b is suppressed when the spacer film 110 is formed.

[FIG. 13]

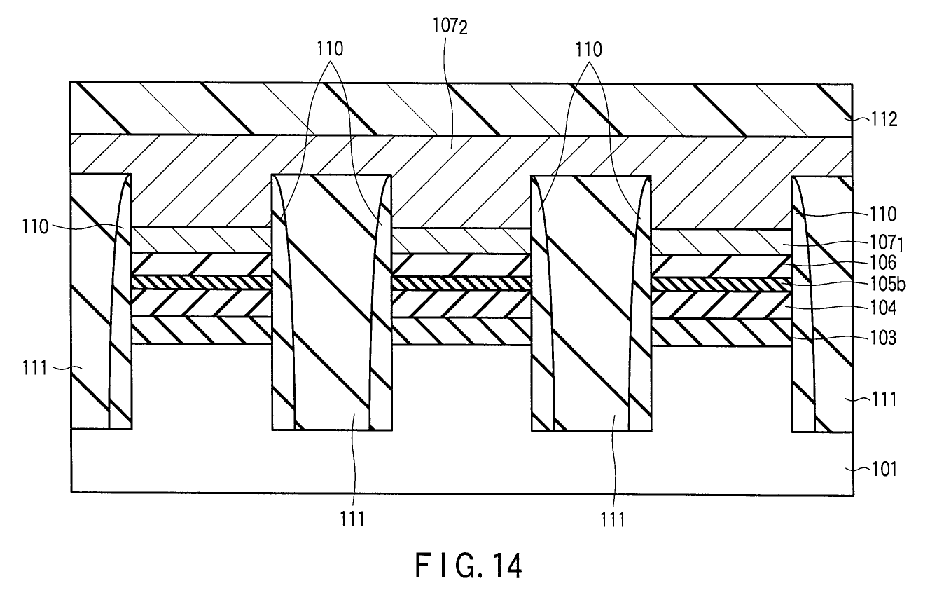

An isolation insulating film 111 of a silicon oxide is formed on the entire surface by CVD process using TEOS and ozone as source gases around a normal pressure, thereafter, the surface is planarized by CMP process. At this time, as described above, as the charge storage layers 104, 105b and control gate electrode 107₁ are protected by the spacer film 110, the reduction of the charge trap density is suppressed.

[FIG. 14]

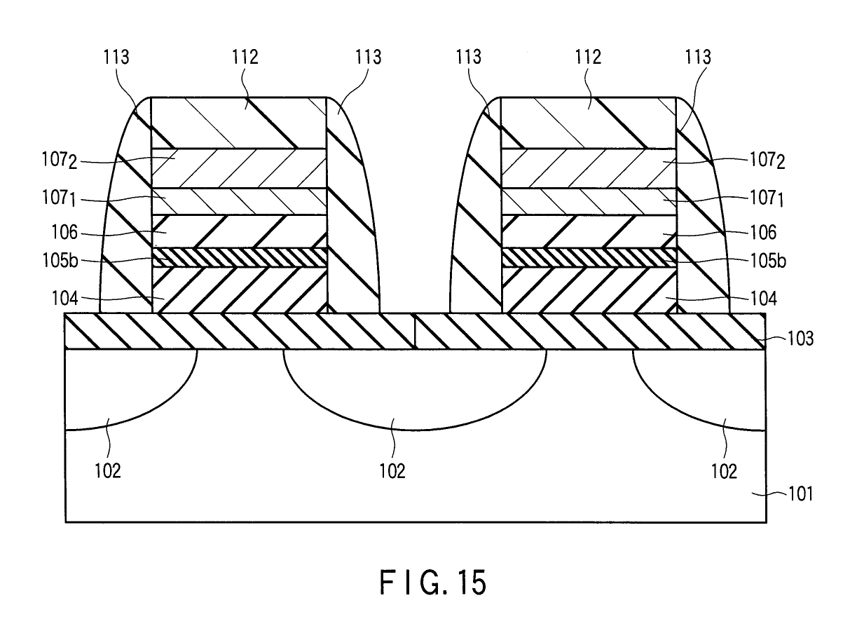

The mask 108 is removed, and the upper surface of the control gate electrode 107₁ is exposed. A control gate electrode 107₂ is formed to contact with the control gate electrode 107₁. The step of forming the control gate electrode 107₂ includes a step of forming a conductive film of polycrystalline silicon or metal to be the control gate electrode 107₂, a step of forming mask on the conductive film, and a step of processing the conductive film by RIE process using the mask 112.

[FIG. 15]

The source/drain regions 102 are formed on surface of the semiconductor substrate 101. FIG. 15 is a cross-sectional view in the channel length direction. FIGS. 7 to 14 are cross-sectional views in the channel width direction, and the source/drain regions 102 are not seen in FIGS. 7 to 14, then the cross-sectional view in the channel length direction is shown in FIG. 15.

By using the similar method as the step of FIG. 12, insulating film (spacer film) 113 is formed on cell sidewall in the channel length direction by CVD process using carbon-free SiH₂Cl₂ and N₂O, or SiCl₄ and N₂O as source gases and RIE process (anisotropic etching), and the width of the spacer film 113 is set such that oxygen radical generated from the ozone is deactivated during the oxygen radical diffuses in the spacer film 110. The width is, for example, 3 nm or more.

The regions between the cells are filled with a silicon oxide film by CVD process. The CVD process is performed using TEOS gas and ozone as source gases at low temperature, and at normal pressure or small low pressure. At this time, in a similar manner as the step of FIG. 13, the charge storage layers 104, 105b and the control gate electrode 107₁ are protected by the spacer film 113, thereby the reduction of the trap density is suppressed. Thereafter, known steps are carried out, and the semiconductor device including nonvolatile semiconductor memory comprising the memory cell having a SONOS structure is completed. The nonvolatile semiconductor memory is, for example, a NAND flash memory.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
a semiconductor substrate;
a tunnel insulating film provided on the semiconductor substrate;
a charge storage layer provided on the tunnel insulating film;
a block insulating film provided on the charge storage layer; and
a control gate electrode provided on the block insulating film,
the charge storage layer comprising a plurality of layers including first and second charge storage layers, the second charge storage layer being provided on a nearest side of the block insulating film, the first charge storage layer being provided between the tunnel insulating film and the second charge storage layer, the second charge storage layer having a higher trap density than the first charge storage layer, the second charge storage layer having a smaller band gap than the first charge storage layer, and the second charge storage layer having a higher permittivity than the first charge storage layer and a silicon nitride film.

2. The semiconductor device according to claim 1, wherein the first charge storage layer is a silicon nitride film.

3. The semiconductor device according to claim 2, wherein the silicon nitride film has nitride/silicon composition ration which is higher than stoichiometric ration of a silicon nitride film.

4. The semiconductor device according to claim 1, wherein the second charge storage layer is an insulating film including Hf or Zr.

5. The semiconductor device according to claim 4, wherein the insulating film Hf or Zr is a SiON film including Hf, an AlO film including Hf, an Hafnium oxide, an ON film including Hf, SiON film including Zr, an AlO film including Zr, an O₂ film including Zr, or an ON film including Zr.

6. The semiconductor device according to claim 1, further comprising a third charge storage layer provided between the first and second charge storage layers.

7. The semiconductor device according to claim 6, wherein the first charge storage layer is a silicon nitride film, and the third charge storage layer is a silicon oxynitride film.

8. The semiconductor device according to claim 1, wherein the block insulating film is a silicon oxide film or a high dielectric film having higher permittivity than the silicon oxide film.

9. The semiconductor device according to claim 8, wherein the high dielectric film is an AlO film, an AlO film including Hf, SiO film including Hf or a TaO film.

10. The semiconductor device according to claim 1, wherein the control gate electrode comprises polycrystalline silicon or metal.

11. The semiconductor device according to claim 1, wherein the tunnel insulating film is a silicon oxide film or a silicon oxynitride film.

12. A method for manufacturing a semiconductor device comprising:
forming a tunnel insulating film on a semiconductor substrate;
forming a charge storage layer on the tunnel insulating film, the charge storage layer comprising a plurality of layers including first and second charge storage layers;
performing heat treatment to the charge storage layer in an atmosphere including chlorine;
forming a block insulating film on the charge storage layer, and
forming a control gate electrode on the block insulating film,
wherein the second charge storage layer being provided on a nearest side of the block insulating film, the first charge storage layer being provided between the tunnel insulating film and the second charge storage layer, the second charge storage layer having a higher trap density than the first charge storage layer, the second charge storage layer having a smaller band gap and the second charge storage layer having a higher permittivity than the first charge storage layer and a silicon nitride film.

13. A method for manufacturing a semiconductor device comprising:
forming a tunnel insulating film on a semiconductor substrate;
forming a charge storage layer on the tunnel insulating film the charge storage layer comprising a plurality of layers including first and second charge storage layers;
forming a block insulating film on the charge storage layer in an atmosphere including chlorine; and
forming a control gate electrode on the block insulating film,
wherein the second charge storage layer being provided on a nearest side of the block insulating film, the first charge storage layer being provided between the tunnel insulating film and the second charge storage layer, the second charge storage layer having a higher trap density than the first charge storage layer, the second charge storage layer having a smaller band gap than the first charge storage layer, and the second charge storage layer having a higher permittivity than the first charge storage layer and a silicon nitride film.

14. The method according to claim 12, further comprising forming an insulating film by using gas including chlorine after forming the tunnel insulating film, the charge storage layer, the block insulating film and the control gate, and wherein the insulating film covers side walls of the charge storage layer, the block insulating film and the control gate.

15. The method according to claim 13, further comprising forming an insulating film by using gas including chlorine after forming the charge storage layer, the block insulating film and the control gate, and wherein the insulating film covers side walls of the charge storage layer, the block insulating film and the control gate.

16. The method according to claim 12, wherein the gas including chlorine is an oxidizing atmosphere including HCl, CH₃Cl, or C₂H₄Cl₂.

17. The method according to claim 13, wherein the gas including chlorine is an oxidizing atmosphere including HCl, CH₃Cl, or C₂H₄Cl₂.

18. The method according to claim 13, wherein the block insulating film is a silicon oxide film, and source gases of the block insulating film includes SiH₂Cl₂ and N₂O, or SiCl₄ and N₂O.
